(19) United States
(12) Patent Application Publication
(10) Pub. No.: US 2020/0111538 A1
(43) Pub. Date: Apr. 9, 2020

(54) MEMORY SYSTEM WITH DYNAMIC AUTO-REPAIRING FUNCTION AND OPERATING METHOD THEREOF

(71) Applicant: Raydium Semiconductor Corporation

(72) Inventors: Wen-Sheng CHEN, Taoyuan (TW); Yu-Min CHANG, Taipei (TW); Chung-Sung TSAI, New Taipei (TW)

(21) Appl. No.: 16/152,100

(22) Filed: Oct. 4, 2018

(51) Int. Cl. G11C 29/44; G11C 29/38

(52) U.S. Cl. CPC G11C 29/4401; G11C 29/38

(57) ABSTRACT

A memory system with dynamic auto-repairing function and an operation method thereof is described herein. The memory system includes a memory and an automatic detection and repairing circuit. The automatic detection and repairing circuit is coupled to the memory. The automatic detection and repairing circuit includes a self-test unit and a repairing unit. The self-test unit is coupled to the memory. The repairing unit is coupled to the memory and the self-test unit respectively. When the memory system is operated in the initial state, the self-test unit instantly detects the defects in the memory and the repairing unit instantly repairs the defects in the memory. Then, the memory system enters into a working state from the initial state.

### CROSS-REFERENCE TO RELATED APPLICATIONS

This Application claims the benefit of U.S. Provisional Application 62/568,410 filed on Oct. 5, 2017.

### BACKGROUND

### Field

Embodiments of the present disclosure relate to memory; in particular, to a memory system with dynamic auto-repairing function and an operating method thereof.

### Description of the Related Art

In general, most electronic devices are equipped with memory, such as various embedded applications, personal computers, workstations, routers, printers, liquid crystal displays, robots, etc., almost using memory without exception.

However, when the electronic device enters the working state, once the defect or damage occurs in the memory, it is likely to cause the electronic device to malfunction, especially for special electronic devices that are expensive and difficult to repair in the use environment, such as deep-sea detection instruments, meteorological satellites, etc., when working in special environments such as deep sea or space, it is difficult to repair their memory.

### SUMMARY

Therefore, the disclosure provides a memory system with dynamic auto-repairing function and an operating method thereof to solve the above-mentioned problems of the prior arts.

A preferred embodiment of the disclosure is a memory system with dynamic auto-repairing function. In this embodiment, the memory system includes a memory and an automatic detection and repairing circuit. The automatic detection and repairing circuit is coupled to the memory. The automatic detection and repairing circuit includes a self-test unit and a repairing unit. The self-test unit is coupled to the memory. The repairing unit is coupled to the memory and the self-test unit respectively. When the memory system is operated in the initial state, the self-test unit instantly detects the defects in the memory and the repairing unit instantly repairs the defects in the memory. Then, the memory system enters into a working state from the initial state.

In an embodiment, the memory is a repairable static random-access memory (SRAM).

In an embodiment, the self-test unit is a built-in self-test (BIST) circuit.

In an embodiment, every time when the memory system is started and enters into the initial state, the automatic detection and repairing circuit is also started at the same time.

In an embodiment, when the automatic detection and repairing circuit is started, the self-test unit instantly performs defect detection on the memory.

Another preferred embodiment of the disclosure is a method of operating a memory system with dynamic auto-repairing function. The memory system includes a memory and an automatic detection and repairing circuit. The automatic detection and repairing circuit is coupled to the memory. The automatic detection and repairing circuit includes a self-test unit and a repairing unit. The self-test unit is coupled to the memory. The repairing unit is coupled to the memory and the self-test unit respectively. The method includes steps of: (a) when the memory system is operated in an initial state, the self-test unit instantly detecting defects in the memory; (b) the repairing unit repairing the defects in the memory; and (c) the memory system entering into a working state from the initial state.

Compared to the prior art, the memory system with dynamic automatic repair function and the operation method thereof according to the disclosure can automatically detect the defects in the memory through the self-test unit and immediately repair the defects through the repairing unit every time when the memory system starts to enter the initial state, so that the memory system has no defects when it enters the working state from the initial state and the normal operation of the memory system can be maintained, so that the electronic device with the memory system can prolong its service life, especially for the special electronic equipment working in a special environment such as deep sea or space, the memory system with dynamic automatic repair function and the operation method thereof can greatly reduce its maintenance risk and cost.

The advantage and spirit of the disclosure may be understood by the following detailed descriptions together with the appended drawings.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 illustrates a schematic diagram of the memory system with dynamic automatic repair function in an embodiment of the disclosure.

FIG. 2 illustrates a flowchart of the memory system operating method with dynamic automatic repair function in another embodiment of the disclosure.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

A preferred embodiment of the disclosure is a memory system with dynamic automatic repair function. In this embodiment, the memory system with dynamic automatic repair function can be applied to any electronic devices, such as various embedded applications, personal computers, workstations, routers, printers, liquid crystal displays, robots, etc., almost using memory without exception.

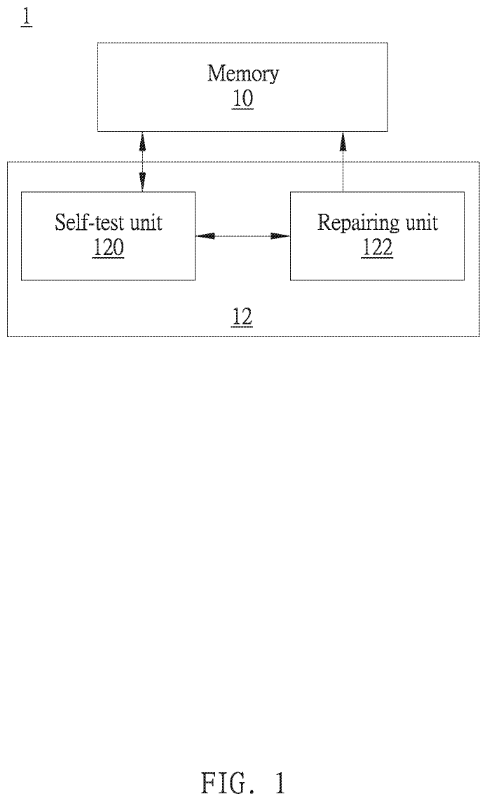

Please refer to FIG. 1. FIG. 1 illustrates a schematic diagram of an embodiment of the memory system with dynamic automatic repair function.

As shown in FIG. 1, the memory system 1 includes a memory 10 and an automatic detection and repairing circuit 12. The automatic detection and repairing circuit 12 is coupled to the memory 10. The automatic detection and repairing circuit 12 includes a self-test unit 120 and a repairing unit 122. The self-test unit 120 is coupled to the memory 10. The repairing unit 122 is coupled to the memory 10 and the self-test unit 120 respectively.

Every time when the memory system 1 is started and enters into an initial state, the automatic detection and repairing circuit 12 will be also started. At this time, the automatic detection and repairing circuit 12 will automatically detect all memory units in the memory 10 through the self-test unit 120 to instantly detect defects in the memory 10.

The self-test unit 120 will send a detection result to the repairing unit 122. The repairing unit 122 will instantly repair the defects in the memory 10 according to the detection result. Then, the memory system 1 will enter into a working state from the initial state and start to work normally.

In practical applications, the memory 10 can be, but not limited to, a repairable static random-access memory (SRAM); the self-test unit 120 can be, but not limited to, a built-in self-test (BIST) circuit.

Another preferred embodiment of the disclosure is a method of operating a memory system with dynamic auto-repairing function. In this embodiment, the memory system includes a memory and an automatic detection and repairing circuit. The automatic detection and repairing circuit is coupled to the memory. The automatic detection and repairing circuit includes a self-test unit and a repairing unit. The self-test unit is coupled to the memory. The repairing unit is coupled to the memory and the self-test unit respectively.

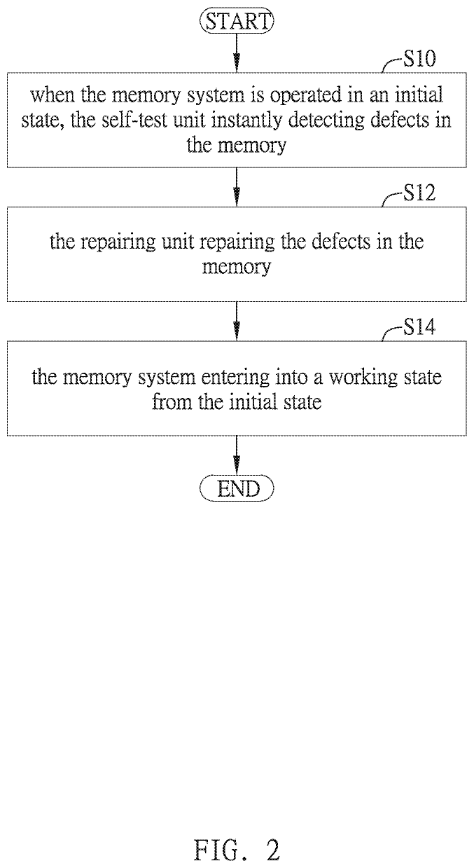

Please refer to FIG. 2. FIG. 2 illustrates a flowchart of an embodiment of the memory system operating method with dynamic automatic repair function. As shown in FIG. 2, the memory system operating method can include steps of:
Step S10: when the memory system is operating in an initial state, the self-test unit instantly detecting defects in the memory;
Step S12: the repairing unit repairing the defects in the memory; and
Step S14: the memory system entering into a working state from the initial state.

Compared to the prior art, the memory system with dynamic automatic repair function and the operation method thereof according to the disclosure can automatically detect the defects in the memory through the self-test unit and immediately repair the defects through the repairing unit every time when the memory system starts to enter the initial state. In this respect, the memory system has no defects when it enters the working state from the initial state and the normal operation of the memory system can be maintained. As a result, the electronic device with the memory system can prolong its service life, especially for the special electronic equipment working in a special environment such as deep sea or space. The memory system with dynamic automatic repair function and the operation method thereof can greatly reduce its maintenance risk and cost.

With the example and explanations above, the features and spirits of the disclosure will be hopefully well described. Those skilled in the art will readily observe that numerous modifications and alterations of the device may be made while retaining the teaching of the disclosure. Accordingly, the above disclosure should be construed as limited only by the metes and bounds of the appended claims

What is claimed is:

1. A memory system with dynamic auto-repairing function, comprising:
a memory; and
an automatic detection and repairing circuit, coupled to the memory, comprising:
a self-test unit, coupled to the memory; and
a repairing unit, coupled to the memory and the self-test unit,
wherein when the memory system is operated in an initial state, the self-test unit instantly detects defects in the memory and the repairing unit repairs the defects in the memory, and then the memory system enters into a working state from the initial state.

2. The memory system with dynamic auto-repairing function of claim 1, wherein the memory is a repairable static random-access memory (SRAM).

3. The memory system with dynamic auto-repairing function of claim 1, wherein the self-test unit is a built-in self-test (BIST) circuit.

4. The memory system with dynamic auto-repairing function of claim 1, wherein every time when the memory system enters into the initial state, the automatic detection and repairing circuit is also started at the same time.

5. The memory system with dynamic auto-repairing function of claim 4, wherein when the automatic detection and repairing circuit is started, the self-test unit instantly performs defect detection on the memory.

6. A method of operating a memory system with dynamic auto-repairing function, the memory system comprising a memory and an automatic detection and repairing circuit, the automatic detection and repairing circuit being coupled to the memory, the automatic detection and repairing circuit comprising a self-test unit and a repairing unit, the self-test unit being coupled to the memory, the repairing unit is coupled to the memory and the self-test unit respectively, the method comprising steps of:
(a) when the memory system is operated in an initial state, the self-test unit instantly detecting defects in the memory;
(b) the repairing unit repairing the defects in the memory; and
(c) the memory system entering into a working state from the initial state.

7. The method of claim 6, wherein the memory is a repairable static random-access memory (SRAM).

8. The method of claim 6, wherein the self-test unit is a built-in self-test (BIST) circuit.

9. The method of claim 6, wherein every time when the memory system is started and enters into the initial state, the automatic detection and repairing circuit is also started at the same time.

10. The method of claim 9, wherein when the automatic detection and repairing circuit is started, the self-test unit instantly performs defect detection on the memory.

11. A method of operating a memory system, the memory system having a memory, a self-test unit coupled to the memory, and a repairing unit coupled to the memory and the self-test unit, the method comprising:
when the memory system is operating in an initial state, instantly detecting defects in the memory using the self-test unit;
repairing the defect in the memory using the repairing unit; and
entering into a working state after repairing.

12. The method of claim 11, wherein the self-test unit is started simultaneously with the memory system entering the initial state.
